(19) United States
(12) Patent Application Publication
(10) Pub. No.: US 2026/0362662 A1
(43) Pub. Date: Nov. 12, 2026

(54) SYSTEM AND METHOD OF COOLING ELECTRONIC CONTROL UNITS WITHIN A VEHICLE

(71) Applicant: GM Global Technology Operations LLC, Detroit, MI (US)

(72) Inventors: Alex Jose Veloso, Rochester Hills, MI (US); Daniel Pinheiro Carlesimo, Rochester Hills, MI (US); Aziz Ulhaq Noori, Troy, MI (US); Pavan Siddartha Aka, South Lyon, MI (US)

(21) Appl. No.: 19/200,135

(22) Filed: May 6, 2025

(51) Int. Cl. H05K 7/20; B60H 1/00

(52) U.S. Cl. CPC H05K 7/20945; B60H 1/00271; B60H 1/00828; H05K 7/20909; B60H 2001/003

(57) ABSTRACT

A system and method of selective cooling of electronic control units (ECU) within a vehicle. The method includes determining a zone containing the ECU within the vehicle, determining a temperature of the ECU is above a predetermined temperature threshold (T1), determining a slope (M) representing a rate of temperature change of the ECU, determining the slope to be above a slope threshold (g), selecting a predetermined heat dissipation strategy based on the slope (M), and executing the selected predetermined heat dissipation strategy by a HVAC system of the vehicle by targeting the zone containing the ECU. The method further includes determining the slope (M) to fall below the slope threshold (g) and reduces the output of the HVAC system in response.

### INTRODUCTION

The present disclosure generally relates to thermal management of electronic control units (ECUs) contained in vehicles, more specifically to a system and method of selective cooling of ECUs within a vehicle based on a rate of temperature change of individual ECUs.

Modern vehicles contain a plurality of electronic control modules, also referred to as electronic control units (ECUs), that contains integrated circuits and/or microprocessors configured to execute specific functions of the vehicles while the vehicles are in an operating mode, also referred to as an On-mode. For example, an engine ECU manages the operation of a vehicle engine, a driver assistant ECU manages the automated braking of a vehicle brake system, and a perception ECU manages the data received by the vehicle sensors. There are ECUs that may be operational while the vehicles are in a non-operating mode, also referred to as an Off-mode. For example, an integrated communications ECU, also known as a Connectivity Hub Module (CHM), manages Wi-Fi hot spot services for customers outside of the vehicle may continue to operate while the vehicle is in the Off-mode.

ECUs, like other power electronics, generate heat while in use. There is a need for continual improvements in systems and methods of cooling ECU, particularly while the vehicle is in the Off-mode, to maximize power savings while minimizing packaging size and mass.

### SUMMARY

According to several aspects, a method of selective cooling of an electronic control unit (ECU) within a vehicle is disclosed. The method includes determining a zone containing the ECU within the vehicle, determining a temperature of the ECU is above a predetermined temperature threshold (T1), determining a slope (M) representing a rate of temperature change of the ECU, selecting a predetermined heat dissipation strategy based on the slope (M), and executing the selected predetermined heat dissipation strategy by an air conditioning system of the vehicle by targeting the zone containing the ECU.

In an additional aspect of the present disclosure, selecting the predetermined heat dissipation strategy based on the slope (M) includes: comparing the slope (M) to a plurality of predetermined slope thresholds having respective predetermined heat dissipation strategies, selecting one of the plurality of predetermined slope thresholds having a slope immediately less than the slope M, and executing the selected predetermined heat dissipation strategy by at least providing an airflow to the zone containing the ECU.

In another aspect of the present disclosure, determining the slope (M) is equal to or greater than a predetermined slope (g) before comparing the slope (M) to the plurality of predetermined slope thresholds having respective predetermined heat dissipation strategies.

In another aspect of the present disclosure, the plurality of predetermined slope thresholds include a slope (a), a slope (b), and up to a slope (N), wherein a heat dissipation strategy respective to slope (a) includes setting a blower of the AC system to a first setting, a heat dissipation strategy respective to slope (b) includes setting the blower of the AC system to a second setting, and a heat dissipation strategy respective to slope (N) includes setting a blower of the AC system to an N setting, wherein the first setting is a lowest airflow output and N is a highest airflow output of the blower.

In another aspect of the present disclosure, the heat dissipation strategy respective to slope (N) further includes activating the AC compressor to generate a conditioned airflow.

In another aspect of the present disclosure, the method further includes: determining the slope (M) is less than a predetermined slope threshold (g), assigning a value to “i” in response to the slope (M) is less than the predetermined slope threshold (g), selecting one of a plurality of predetermined heat dissipation strategies based on the value of i (i=value); and executing the selected one of the plurality of predetermined heat dissipation strategies based on the assigned value of i.

In another aspect of the present disclosure, the plurality of predetermined heat dissipation strategies includes: setting a blower of the AC system to an off-setting when the integer value of i is 1 (i=1), setting the blower of the AC system to a first setting when i=2 and reset value of i to equal 1 (i=1); setting the blower of the AC system to a second setting when i=3 and reset i to equal 2 (i=2), and setting the blower of the AC system to an N−1 setting and when i=N, wherein N is an integer corresponding to the highest setting of the blower.

In another aspect of the present disclosure, wherein the determining a temperature of the ECU is above a predetermined temperature threshold (T1) is performed in real time.

In another aspect of the present disclosure, the method further includes determining the vehicle is in a Vehicle OFF-mode before determining the temperature of the electric control unit (ECU) is above the predetermined temperature threshold (T1).

In another aspect of the present disclosure, executing the predetermined heat dissipation strategy includes actuating vents in an air distribution conduit to direct an air flow, induced by a blower of the AC system, to the zone containing the ECU.

According to several aspects, an electronic control unit (ECU) disposed within a vehicle having an air conditioning (AC) system, wherein the ECU comprises: a temperature sensor configured to gather temperature data on the ECU, a processor, a non-transitory computer readable medium having instructions stored thereon for cooling of the ECU. The instructions upon execution by a processor, cause the processor to: analyze the temperature data to determine a temperature of the ECU is above a predetermined temperature threshold (T1), determine a slope (M) representing a rate of temperature change of the ECU, determine the slope (M) is one of: (i) above a slope threshold (g) and (ii) below the slope threshold (g), instructing the AC system to execute a first predetermined heat dissipation strategy in response to the slope (M) is determined to be equal to or greater than the slope threshold (g), and instruct the AC system to execute a second predetermined heat dissipation strategy in response to the slope (M) is determined to be less than the slope threshold (g).

In an additional aspect of the present disclosure, the first predetermined heat dissipation strategy includes increasing a rate of an airflow into the zone in which the ECU is disposed. The second predetermined heat dissipation strategy includes decreasing the rate of the airflow into the zone in which the ECU is disposed.

In another aspect of the present disclosure, the ECU further includes instructions to cause the processor to: compare the slope (M) with a series of predetermined increasing slope thresholds, wherein each of the predetermined increasing slope thresholds includes a respective predetermined heat dissipation strategy; select one of the predetermined increasing slope thresholds having a slope equal to or immediately less than the slope (M); and execute the predetermined heat dissipation strategy respective to the selected one of the predetermined slope thresholds.

In another aspect of the present disclosure, a steeper predetermined increasing slope corresponds a respective predetermined heat dissipation strategy having a greater airflow output.

In another aspect of the present disclosure, the series of predetermined increasing slope thresholds includes a first slope threshold (a) having a lowest slope angle and a last slope threshold (n) having a highest slope angle. The first slope threshold is respective to a 1^{st} predetermined heat dissipation strategy including instructing the AC system to output an airflow rate at a lowest output. The last slope threshold (n) is respective to a n^{th} predetermined heat dissipation strategy including instructing the AC system to output an airflow rate at a highest output and activate a compressor to output a cooled airflow. The integer “n” is equal to a number of blower speed of the AC system.

In another aspect of the present disclosure, the ECU is a Connectivity Hub Module (CHM) configured to manages Wi-Fi hot spot services on demand while the vehicle is in an Off-mode.

According to several aspects, a system for selective cooling of ECU within a vehicle is provided. The system includes a heating, ventilation, and air conditioning (HVAC) system; at least one ECU disposed within a zone of the vehicle; and a temperature sensor configured to gather temperature data on the ECU. The ECU is configured to receive the temperature data and determine a slope (M) representing a rate of temperature change of the ECU, compare the slope (M) with a plurality of slope thresholds, select one of the plurality of slope thresholds, wherein the selected one of the plurality of slope thresholds includes a slope immediately less than the slope (M), and execute the predetermined cooling strategy respected to the selected one of the plurality of slope thresholds. The predetermined cooling strategy includes the HVAC system 160 directing an airflow to the zone of the vehicle in which the ECU is disposed.

In an additional aspect of the disclosure, the ECU is configured to: determine the slope (M) is one of: (i) above a slope threshold (g) and (ii) below the slope threshold (g). In response to the slope (M) is determined to be equal to or greater than the slope threshold (g), the ECU compares the slope (M) with a series of predetermined increasing slope thresholds, select one of the predetermined increasing slope thresholds having a slope equal to or immediately less than the slope (M), and execute a predetermined heat dissipation strategy respective to the predetermined increasing slope thresholds. In response to the slope (M) is determined to be less than the slope threshold (g), the ECU assigns a value to i (i=value) and execute a predetermined heat dissipation strategy based on i=1.

In another aspect of the present disclosure, the slope (M) is less than threshold slope (g) condition in subsequent loop, a new integer value is assigned to i, in which the new integer value is one less than the prior assigned value to i.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way

FIG. 1 is a functional diagram of a vehicle having a system for selective cooling of electronic control units (ECUs) within the vehicle, according to an exemplary embodiment; and

FIG. 2 a flow block diagram of a method for selective cooling of ECUs within the vehicle, according to an exemplary embodiment.

### DETAILED DESCRIPTION

The following description is merely exemplary in nature and is not intended to limit the present disclosure, application, or uses. The illustrated embodiments are disclosed with reference to the drawings, wherein like numerals indicate corresponding parts throughout the several drawings. The figures are not necessarily to scale and some features may be exaggerated or minimized to show details of particular features. The specific structural and functional details disclosed are not intended to be interpreted as limiting, but as a representative basis for teaching one skilled in the art as to how to practice the disclosed concepts.

As used herein, the terms module, component module, control module, controller, or electronic control unit (ECU) refer to any hardware, software, firmware, electronic control component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may conduct a variety of functions under the control of one or more microprocessors or other control devices. In addition, those skilled in the art will appreciate that embodiments of the present disclosure may be practiced in conjunction with any number of systems, and that the systems described herein is merely exemplary embodiments of the present disclosure.

The connecting lines shown in the various figures contained herein are intended to represent example functional relationships and/or physical couplings between the various elements. Conventional techniques may be used for signal processing, data transmission, signaling, control, and other functional aspects of the systems (and the individual operating components of the systems) may not be described in detail herein. It should be noted that many alternative or additional functional relationships or physical connections may be present in an embodiment of the present disclosure.

Terms such as “first,” “second,” and other numerical terms when used herein do not imply a sequence or order unless clearly indicated by the context. Thus, a first step, element, component, region, layer, or section discussed below could be termed a second step, element, component, region, layer, or section without departing from the teachings of the example embodiments.

The Method 200 described below provides a simple, but eloquent solution, of providing active cooling to selected Electronic Control Units (ECU) while a vehicle is in the Vehicle Off-mode. The Method 200 detects and mitigates elevated ambient temperatures of an ECU and utilizes the air conditioning (A/C) system to selectively cool the ECU. Depending on the ambient temperature and the rate of increase/decrease of the ambient temperature of the ECU, the Method 200 adjusts the AC system operation modes such as providing an airflow to a zone containing the ECU and adjusting blower speed, air recirculation, and AC compressor settings with optimized power consumption.

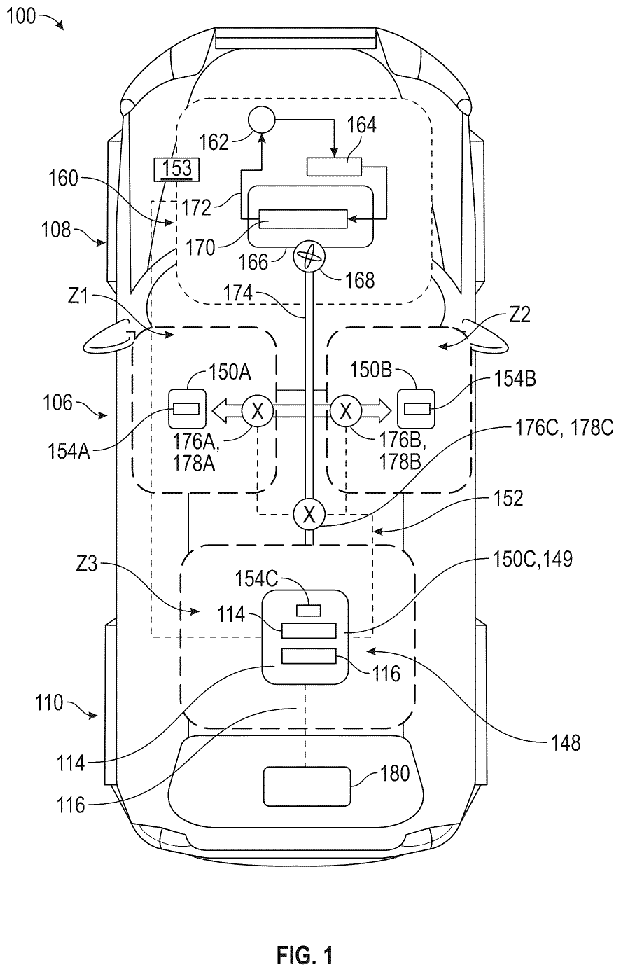

FIG. 1 is a functional diagram of a vehicle 100 having a system for cooling electronic units within the vehicle. The vehicle 100 generally includes a body 106, front wheels 108, and rear wheels 110. The front wheels 108 and the rear wheels 110 are each rotationally coupled to the body 106 near respective corners of the body 106. The vehicle 100 includes an engine (not shown) such as an internal combustion engine, an electric engine, and/or a hybrid engine configured to propel the vehicle 100. The vehicle 100 may also include various electrical systems such as ignition systems, advanced driver assisted systems (ADAS), and communication systems 148 required for the operation of the vehicle 100. A plurality of electronic control units (ECUs) 150A, 150B, 150C are disposed in various locations within the vehicle body 106 for the control and management of such electrical systems. While only 3 ECUs 150A, 150B, 150C are shown, the vehicle 100 may contain dozens to hundreds of ECUs disposed throughout the interior of the vehicle 100. Although the vehicle 100 is shown as a sedan, it is envisioned that that the vehicle 100 may include other types of on-road vehicle, such as a pickup truck, a coupe, a sport utility vehicle (SUVs), a recreational vehicle (RVs), and a motorcycle.

ECUs are essentially small computers that manage and monitor various electrical systems and subsystems in the vehicle 100 necessary to for the operation of the vehicle 100 while the vehicle 100 is in an on-mode, also referred to as a Vehicle ON-mode. Vehicle ON-mode means the vehicle ignition system is activated, allowing the electrical systems of the vehicle 100 to power up and the vehicle engine is activated to propel the vehicle 100 on demand. Certain ECUs may also be active upon demand when the vehicle 100 is in an off-mode, also referred to as a Vehicle OFF-mode. Vehicle OFF-mode means the vehicle ignition system is powered down such that most of the electrical systems are in a low power or parasitic sleep state and the vehicle engine is deactivated. ECUs can communicate with each other via the vehicle's network, typically using protocols such as Controller Area Network (CAN) 152.

Non-limiting examples of ECUs that manage systems while the vehicle is in the Vehicle ON-mode include: Engine Control Module (ECM) configured to manage the engine's performance, including fuel injection, ignition timing, and emission controls; Climate Control Unit (CCU) 153 configured to regulate the heating, ventilation, and air conditioning (HVAC) system 160 to maintain the desired cabin temperature and air quality; and Suspension Control Units (SCU) configured to manage adaptive or active suspension system, adjust the suspension settings to improve ride comfort, and handling based on driving conditions. Non-limiting examples of ECUs that manage systems while the vehicle is in the Vehicle Off-mode include Infotainment Control Modules (ICM) configured to control the vehicle's entertainment and information system, including the audio system, navigation, and connectivity features; Battery Management Unit (BMU) configured to monitor and manage the battery pack performance, including charging, discharging, and battery thermal management; and Connectivity Hub Module (CHM) 149 configured to manage the vehicle communications system 148.

A non-limiting example of a vehicle communication system 148 includes one or more communication transceivers configured to wirelessly communicate information, or data, to and from other remote entities, such as other connected vehicles utilizing Vehicle-to-Vehicle (V2V) communication, infrastructure units such as Road-Side Units (RSU) and Mobile Edge Computing (MEC) utilizing Vehicle-to-Infrastructure (V2I) communications, and/or cloud computing service providers 150 utilizing telecommunications. The communication transceiver may be configured to communicate via a wireless local area network (WLAN) using IEEE 802.11 standards or by using cellular data communication. However, additional or alternate communication methods, such as a dedicated short-range communications (DSRC) channel, are also considered within the scope of the present disclosure. DSRC channels refer to one-way or two-way short-range to medium-range wireless communication channels specifically designed for automotive use and a corresponding set of protocols and standards. The CHM 149 is configured to control one or more features of the vehicle communications system 148 while the vehicle 100 is in the Vehicle ON-mode and upon demand while the vehicle 100 is in the vehicle OFF-mode.

Heat can have undesirable effects on the ECUs disposed within vehicles. Excess temperatures can cause the ECUs to operate less efficiently, resulting in slower processing speeds, delayed responses, and reduced performance. Repeated exposures to elevated temperature cycles can cause thermal stress resulting in potentially reduced lifespan, or even premature failure of the ECUs. Temperature sensors 154A, 154B, 154C may be integrated with the respective ECUs 150A, 150B, 150C or disposed proximal to the respective ECU. The Temperature sensors 154A, 154B, 154C are configured to gather ambient temperature data on the individual ECUs and communicate the gathered temperature data to the respective ECUs 150A, 150B, 150C. Non-limiting examples of temperature sensors include thermocouples, resistance temperature detectors (RTD), thermistors, and semiconductor based integrated circuits.

Individual ECUs may be equipped with active heat dissipation solutions such local fans, thermoelectric couples (TEC), and/or liquid cooling systems to manage the effects of heat on the ECUs. Such active heat dissipation solutions require additional components, thus resulting in additional complexity, packaging bulk, mass, and cost. The following disclosure provides a simple, but eloquent, solution of mitigating heat effects on ECUs, especially while the vehicle is in the Vehicle Off-mode, by utilizing the existing HVAC system 160, to selectively cool ECUs based on rates of temperature change of the ECUs and the location of the affected ECU. By utilizing the existing HVAC system 160 eliminates the need to install additional active cooling components, other than the addition of a temperature sensor on or adjacent to the individual ECUs. It should be appreciated that the air conditioning portion of the HVAC system 160 is utilized to cool the ECU, therefore the HVAC system 160 is also referred to as an air conditioning (AC) system 160.

The majority of modern vehicles includes an HVAC system 160 configured to provide conditioned air for the comfort of occupants within the cabin of the vehicle. The HVAC system 160 includes a compressor 162, a condenser 164, and a housing 166 containing a blower assembly 168, a heater core (not shown), and an evaporator 170. The compressor 162 may be electrically powered and is adapted to compress and circulate a refrigerant 172 through the evaporator 170 and condenser 164. The evaporator 170 is adapted evaporate a compressed refrigerant 172 to cool an airflow passing through the housing 166. The housing 166 is in fluid communication with an air distribution conduit 174. The blower assembly 168 is electrically powered to draw air into the housing 166 and induce an air flow through the evaporator 170 and out through the air distribution conduit 174 into the interior of the vehicle 100. Air flow into the housing 166 may be from the external environments or recirculated from the interior of the vehicle 100.

The air distribution conduit 174 includes a plurality of outlets 176A, 176B, 176C directed to multiples zones within the vehicle 100. The plurality of outlets 176A, 176B, 176C may be provided with electrically actuated vents 178A, 178B, 178C configured to selectively direct air flow to one or more predetermined zones. In a non-limiting example, Zone 1 (Z1) is the front driver compartment, Zone 2 (Z2) is the front passenger compartment, and Zone 3 (Z3) is the rear passenger compartment. The HVAC system 160 is managed by the Climate Control Unit (CCU) 153 in communications with the individual ECUs. The CCU 153 is configured to receive instructions from the one or more ECUs to control the compressor 162, blower assembly 168, and electrically activated vents 178A, 178B, 178C to selectively deliver an air flow or a conditioned air flow to a zone in which the one or more ECUs reside.

An exemplary ECU 150C includes at least one processor 114 and a non-transitory computer readable storage device or media 116. The non-transitory computer readable storage device or media 116 includes machine-readable instructions that when executed by the processor 114, cause the processors 114 to execute the Method 200, as described below, to manage the cooling of the ECU 150C based on a rate of temperature change of the ECU 150C. The processor 114 may be a custom made or commercially available processor, a central processing unit (CPU), a graphics processing unit (GPU), an auxiliary processor among several processors associated with the ECU, a semiconductor-based microprocessor (in the form of a microchip or chip set), a macro processor, a combination thereof, or generally a device for executing instructions.

The computer readable storage device or media 116 may include volatile and nonvolatile storage in read-only memory (ROM), random-access memory (RAM), and keep-alive memory (KAM), for example. The vehicle computer-readable storage device or media 116 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions to execute the Method 200 described in detail below. The exemplary ECU 150C may be that of a CHM 149 and includes executable instructions for the management of the vehicle communications system 148. It should be appreciated that portions of the Method 200 may be executed by multiple distributed ECUs, and/or a central dedicated ECU.

The ECUs 150A, 150B, 150C, respective temperature sensors 154A, 154B, 154C, and HVAC system 160 including the compressor 162, blower assembly 168, and electrically operated vents 178A, 178B, 178C may be powered by on board power storage device 180. Exemplary ECU power modes includes a Sleep Mode, a Start-up Mode, and a Run Mode. Sleep mode means the ECU is in a low-power state (i.e. low parasitic current). Start-up mode means the ECU is initializing or powering up. Run Mode means the ECU is powered up and actively controlling the vehicle systems. The ECUs are typically in the Sleep Mode when the vehicle is in the Vehicle OFF-mode. However, certain ECUs, such as the CHM 149 and BMU, may be initialized into a Run Mode, usually upon demand by a user, while the vehicle remains in the Vehicle OFF-mode.

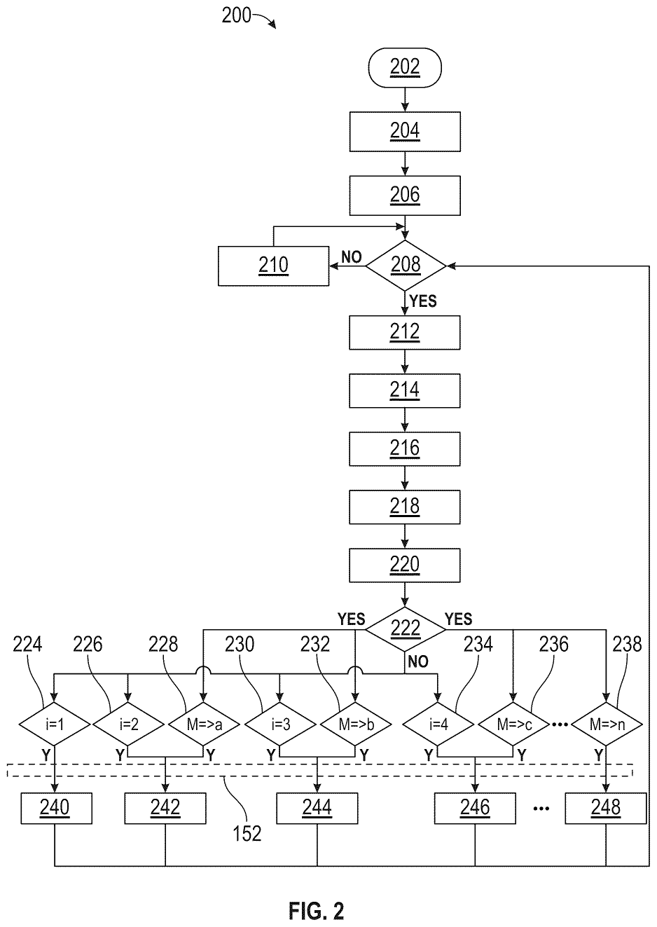

FIG. 2 shows a flow block diagram of a Method 200 for cooling ECUs within the vehicle 100. The Method 200 begins at Block 202, the vehicle 100 transitions to a Vehicle OFF-mode. Proceeding to Block 204.

At Block 204, at least one ECU transitions to a Sleep Mode in response to the vehicle 100 transitioned to the Vehicle OFF-mode. The at least one ECU is capable of reinitializing to the Run Mode upon demand by a user or by a vehicle system while the Vehicle 100 remains in the Vehicle OFF-mode. A value of “i”, also referred to as an i-value, is set at 0 (i=0). Proceeding to Block 206.

At Block 206, the at least one ECU transitions to a Run-mode while the vehicle remains in the Vehicle OFF-mode in response to a user demand or a predetermined system operation. In a non-limiting example, the at least one ECU is a CHM 149 configured to provide hot spot services upon demand by a user outside of the vehicle 100. In another non-limiting example, the ECU is a Battery Management Unit (BMU) configured to monitor the electrical charging of the vehicle's power storage device 180. Yet in another non-limiting example, the ECU is Door Control Unit (DCU) listening for a remote command to unlock the doors or activate the honk and/or flash the lights of the vehicle 100. Proceeding to Block 208.

At Block 208, the temperature sensor of the at least one ECU continuously gather temperature data in real time and communicates the temperature data to the at least one ECU. The at least one ECU receives the temperature data and determines if a current temperature of the at least one ECU is above a predetermined temperature threshold (T1). If the temperature is below T1, the Method 200 proceeds to Block 210. At Block 210, no thermal mitigation is requested and the Method 200 returns to Block 208. Otherwise, if the current temperature is above T1, the Method 200 proceeds to Block 212.

At Block 212, the at least one ECU waits for a predetermined amount of time(S) and records a time stamp S2. Proceeding to Block 214.

At Block 214, the ECU determines a temperature (T2) of the at least one ECU at time stamp S2. Proceeding to Block 216.

At Block 216, the ECU waits for the predetermined amount of time (S) and records a time stamp S3. Proceeding to Block 218.

At Block 218, the ECU determines a temperature (T3) of the at least one ECU at time stamp S3. Proceeding to Block 220.

At Block 220, the ECU determines a slope (M) defined by: [(T3−T2)]/[S3−S2)]. The slope (M) represents the rate of temperature change of the at least one ECU. A positive slope, an inclining slope showing a temperature increase with respect to time, represents a temperature rate increase of the at least one ECU. A negative slope, a declining slope showing a temperature decrease with respect to time, represents a temperature rate decrease of the at least one ECU. A steeper positive slope (M), the higher the rate of temperature change of the at least one ECU. Proceeding to Block 222.

At Block 222, the ECU determines if the slope (M) is less than, equal to, or greater than a predetermined slope threshold (g). The predetermined slope threshold (g) represents a predetermined rate of temperature change that would warrant a thermal mitigation request. A value of “1” is assigned to a variable “i” (i=1) in the first pass or loop of the Method 200. In subsequent passes of the Method 200 while the vehicle 100 remains in the OFF-Mode, the variable “i”, also referred to as an i-value, may remain as 1 or assigned a different integer value as disclosed below.

In response to the slope (M) is equal to or greater than the predetermined slope threshold (g), the Method 200 proceeds to Block 228 if slope (M) is greater than a predetermined slope (a) and less than a predetermined slope (b); the Method 200 proceeds to one of Block 232 if slope (M) is greater than the predetermined slope (b) and less than a predetermined slope (c); the Method 200 proceeds to one of Block 236 if slope (M) is greater than a predetermined slope (c) and less than a predetermined slope (N). In other words, the Method 200 proceeds to a block corresponding to a predetermined slope thresholds having a slope equal to or immediately less than the slope M.

The predetermined slope thresholds (a)-(n) are all positive slopes representing predetermined rates of temperature change thresholds of the at least one ECU. The predetermined slope thresholds (a)-(n) are progressively steeper, in which the predetermined slope threshold (a) is the least steep slope (slowest rate of temperature change) and predetermined slope threshold (n) is the steepest slope (highest rate of temperature change). The Method 200 proceeds to one of Block 242, Block 244, Block 246, and Block 248 from Block 228, Block 232, Block 236, and 238, respectively.

For example, if the slope M is greater than the predetermined slope threshold (a) and less than the predetermined slope (b), the Method 200 proceeds to Block 242 from Block 228; if the slope M is greater than the predetermined slope threshold (b) and less than the predetermined slope (c), the Method 200 proceeds to Block 244 from Block 232; if the slope M is greater than the predetermined slope threshold (c) and less than the predetermined slope (d), the Method 200 proceeds to Block 246 from Block 236; and if the slope M is greater than the predetermined slope threshold (n), the Method 200 proceeds to Block 248 from Block 238.

Block 242, Block 244, Block 246, and Block 248 are predetermined escalating thermal mitigations using the HVAC system 160 of the vehicle 100 to provide cooling to the zone of the vehicle containing the at least one ECU. The predetermined thermal mitigation levels are based on the location (zone), current temperature, and the rate of temperature change (slope M) of the at least one ECU. The at least one ECU communicates with the CCU 153, via the Controller Area Network (CAN) 152, configure the HVAC system to execute at least one of the predetermined escalating thermal mitigations.

Predetermined escalating thermal mitigation levels means in each subsequent block, from Block 242 to Block 248, an additional function of the HVAC system 160 is activated to cool the zone within which the at least one ECU is located, thereby cooling the at least one ECU. In non-limiting examples, at Block 242, a vent is open in the Zone where the at least one ECU is located and the blower assembly is set at level 1 (lowest volume air flow); at Block 244, the blower assembly is set at level 2 (low to mid volume air flow); at Block 246, the blower assembly is set at level 3 (mid to high volume air flow; and at Block 248, the blower assembly is set at level N, where N is the highest volume air flow, and the compressor is activated to generate cool air.

It should be appreciated that there may be additional levels of thermal mitigation between level 3 (Block 246) and the level N (Block 248). The integer N may be based on the number of possible blower speed settings. For example, for a HVAC system have a blow assembly capable of outputting 6 blower speed, then N=6. The Climate Control Unit (CCU) 153 instructs the HVAC system 160 to execute the thermal mitigation based on one of the Blocks 242, 244, 246, 248 as determined by the at least one ECU. The i-value is re-assigned based on the determined Block 242, 244, 246, and 248. For example, the i-value is set to 1 (i=1) if Block 242 was determined, the i value is set to 2 (i=2) if Block 244 was determined, the i value is set to 3 (i=3) if Block 246 was determined, and the i value is set to N (i=N) if Block 248 was determined. From one of Blocks 242, 244, 246, and 248, the Method 200 returns, loops back, to Block 208 and continues until the vehicle 100 returns to the Vehicle On-mode.

Referring back to Block 222, as described above, the ECU determines if the slope (M) is less than, equal to, or greater than a predetermined slope threshold (g). In the first pass of the Method 200, the ECU assigns an i-value equal to 1 (i=1). In subsequent passes of the Method 200, the i value may remain as 1 or assigned a different integer value as described above. In response to the slope (M) is less than the predetermined slope threshold (g), the Method 200 proceeds to one of Block 224, Block 226, Block 230, Block 234 based on the value of i. For example, for i=1, the Method 200 proceeds to Block 224 and then to Block 240; for i=2, the Method 200 proceeds to Block 226 and then to Block 242; for i=3, the Method 200 proceeds to Block 230 and then to Block 244; and for i=4, the Method 200 proceeds to Block 234 then to Block 246.

At Block 240, the at least one ECU communicates with the CCU 153 Module, via the Controller Area Network (CAN) 152, to set the blower assembly in an Off-mode and returns to Block 208 to reiterate the Method 200. At Block 242, the CCU 153 commands the HVAC system 160 to set the blower speed to a 1^{st} setting (lowest airflow output) and opens the vent for the zone containing the at least ECU. At Block 244, the CCU 153 commands the HVAC system 160 to set the blower speed to a 2^{nd} setting and maintain the open vent nearest to the affected ECU. At Block 246, the CCU 153 commands the HVAC system 160 to set the blower speed to a 3rd setting and maintain the open vent to the affected ECU.

In yet another exemplary operation, the Method 200 may have 6 predetermined slope thresholds, “a”, “b”, “c”, “d”, “e”, “f” based on 6 possible blower speeds. Wherein “a” is the entry ambient temperature increase rate (i.e. least steep slope), “b” is the entry plus ambient temperature increase rate, “c” is the mid ambient temperature increase rate, “d” is the mid plus ambient temperature increase rate, “e” is the high ambient temperature increase rate, and “f” is the high plus ambient temperature increase rate (i.e. steepest slope), which means that “f” will set the Blower to operates a the maximum speed, with air circulation open and AC compressor on. In this example:
“i” is set to equal 6 (i=6) when “M”>=“f”;
“i” is set to equal 5 (i=5) when “M”>=“e”;
“i” is set to equal 4 (i=4) when “M”>=“d”;
“i” is set to equal 3 (i=3) when “M”>=“c”;
“i” is set to equal 2 (i=2) when “M”>=“b”;
“i” is set to equal 1 (i=1) when “M”>=“a”;

Thus, when “i”=6, and slope (M) less than threshold slope (g), the Blower is be set to the next lower speed (e.g. Speed 5), with air circulation open and AC compressor off. If slope (M) <threshold slope (g) condition is persistent, the Blower Speed will be reduced in each loop, until completely off, when “i”=1.

In another exemplary operation, if the slope “M” is equal to or greater than then threshold (g), which is a parameter that indicate a high ambient temperature increase rate, Method 200 will set the Blower Speed & Open-Air Recirculation as a function of how high the slope “M” is. If the “M” is equal to or greater than threshold (a), which is the entry ambient temperature increase rate, the Blower will be set to work at lower speed here called as “1” while will set Air Circulation to “Open” to allow get in fresh air to the cabinet. In an immediate subsequent repeat of the Method 200, if the ambient Temperature still is greater than (T1), the slope (M) is calculated again. At this time if the slope (M) is greater than predetermined slope threshold (b), which is the entry plus ambient temperature increase rate, the Blower will be set to Mid speed here called as “2” while will set Air Circulation to “Open” to allow get in fresh air to the cabinet.

The description of the present disclosure is merely exemplary in nature and variations that do not depart from the general sense of the present disclosure are intended to be within the scope of the present disclosure. Such variations are not to be regarded as a departure from the spirit and scope of the present disclosure.

What is claimed is:

1. A method of selective cooling of an electronic control unit (ECU) within a vehicle, comprising:
determining a zone containing the ECU within the vehicle;
determining a temperature of the ECU is above a predetermined temperature threshold (T1);
determining a slope (M) representing a rate of temperature change of the ECU;
selecting a predetermined heat dissipation strategy based on the slope (M); and
executing the selected predetermined heat dissipation strategy by an air conditioning (AC) system of the vehicle by targeting the zone containing the ECU.

2. The method of claim 1, wherein selecting the predetermined heat dissipation strategy based on the slope (M) comprises:
comparing the slope (M) to a plurality of predetermined slope thresholds having respective predetermined heat dissipation strategies;
selecting one of the plurality of predetermined slope thresholds having a slope immediately less than the slope M; and
executing the predetermined heat dissipation strategy respective to the selected one of the plurality of predetermined slope thresholds.

3. The method of claim 2, further comprising:
determining the slope (M) is equal to or greater than a predetermined slope threshold (g) before comparing the slope (M) to the plurality of predetermined slope thresholds having respective predetermined heat dissipation strategies.

4. The method of claim 3, wherein the plurality of predetermined slope thresholds include a slope (a), a slope (b), and up to a slope (N), wherein a heat dissipation strategy respective to slope (a) includes setting a blower of the AC system to a first setting, a heat dissipation strategy respective to slope (b) includes setting the blower of the AC system to a second setting, and a heat dissipation strategy respective to slope (N) includes setting the blower of the AC system to an N setting, wherein the first setting is a lowest airflow output and N is a highest airflow output of the blower.

5. The method of claim 3, wherein the heat dissipation strategy respective to slope (N) further includes activating an AC compressor to generate a conditioned airflow.

6. The method of claim 1, further comprising:
determining the slope (M) is less than a predetermined slope threshold (g);
assigning a value to “i” (i=value) in response to the slope (M) is less than the predetermined slope threshold (g);
selecting one of a plurality of predetermined heat dissipation strategies based on the assigned i=value; and
executing the selected one of the plurality of predetermined heat dissipation strategies based on the i=value.

7. The method of claim 6, wherein the plurality of predetermined heat dissipation strategies includes:
setting a blower of the AC system to an off-setting when an integer value of i is 1 (i=1);
setting the blower of the AC system to a first setting when i=2;
setting the blower of the AC system to a second setting when i=3 and reset i to equal 2 (i=2); and
setting the blower of the AC system to an N−1 setting and when i=N, wherein N is an integer corresponding to the highest setting of the blower.

8. The method of claim 1, wherein the determining a temperature of the ECU is above a predetermined temperature threshold (T1) is performed in real time.

9. The method of claim 1, further comprising determining the vehicle is in a Vehicle OFF-mode before determining the temperature of the ECU is above the predetermined temperature threshold (T1).

10. The method of claim 1, wherein executing the predetermined heat dissipation strategy includes actuating vents in an air distribution conduit to direct an air flow, induced by a blower of the AC system, to only the zone containing the ECU.

11. An electronic control unit (ECU) disposed within a vehicle having an air conditioning (AC) system, wherein the ECU comprises:
a temperature sensor configured to gather temperature data on the ECU;
a processor;
a non-transitory computer readable medium comprising instructions stored thereon for cooling of the ECU, that upon execution by a processor, cause the processor to:
analyze the temperature data to determine a temperature of the ECU is above a predetermined temperature threshold (T1);
determine a slope (M) representing a rate of temperature change of the ECU;
determine the slope (M) is one of: (i) equal to or greater than a slope threshold (g) and (ii) less than the slope threshold (g);
instruct the AC system to execute a first predetermined heat dissipation strategy in response to the slope (M) is determined to be equal to or greater than the slope threshold (g); and
instruct the AC system to execute a second predetermined heat dissipation strategy in response to the slope (M) is determined to be less than the slope threshold (g).

12. The ECU of claim 11, wherein:
the first predetermined heat dissipation strategy includes increasing a rate of an airflow into a zone in which the ECU is disposed; and
the second predetermined heat dissipation strategy includes decreasing the rate of the airflow into the zone in which the ECU is disposed.

13. The ECU of claim 11, further comprising instructions to cause the processor to:
compare the slope (M) with a series of predetermined increasing slope thresholds, wherein each of the predetermined increasing slope thresholds includes a respective predetermined heat dissipation strategy;
select one of the predetermined increasing slope thresholds having a slope equal to or immediately less than the slope (M); and
execute the predetermined heat dissipation strategy respective to the selected one of the predetermined slope thresholds.

14. The ECU of claim 11, wherein a steeper predetermined increasing slope corresponds a respective predetermined heat dissipation strategy having a greater airflow output.

15. The ECU of claim 13, wherein the series of predetermined increasing slope thresholds includes a first slope threshold (a) having a lowest slope angle and a last slope threshold (n) having a highest slope angle;
wherein the first slope threshold is respective to a 1^{st} predetermined heat dissipation strategy including instructing the AC system to output an airflow rate at a lowest output; and
wherein the last slope threshold (n) is respective to a n^{th} predetermined heat dissipation strategy including instructing the AC system to output an airflow rate at a highest output and activate a compressor to output a cooled airflow.

16. The ECU of claim 15, wherein n is equal to a number of blower speed of the AC system.

17. The ECU of claim 11, wherein the ECU is a Connectivity Hub Module (CHM) configured to manages Wi-Fi hot spot services on demand while the vehicle is in an Off-mode.

18. A system for selective cooling of electronic control units (ECUs) within a vehicle, comprising:
a heating, ventilation, and air conditioning (HVAC) system;
at least one electronic control unit (ECU) disposed within a zone of the vehicle; and
a temperature sensor configured to gather temperature data on the ECU;
wherein the ECU is configured to:
receive the temperature data and determine a slope (M) representing a rate of temperature change of the ECU;
compare the slope (M) with a plurality of slope thresholds, wherein each of the plurality of slope thresholds includes a respective predetermined cooling strategy;
select one of the plurality of slope thresholds, wherein the selected one of the plurality of slope thresholds includes a slope immediately less than the slope (M); and
execute the predetermined cooling strategy respected to the selected one of the plurality of slope thresholds; and
wherein the predetermined cooling strategy includes the HVAC system directing an airflow to the zone of the vehicle in which the ECU is disposed.

19. The system of claim 18, wherein the ECU is configured to:
determine the slope (M) is one of: (i) equal to or greater a slope threshold (g) and (ii) less than the slope threshold (g);
in response to the slope (M) is determined to be equal to or greater than the slope threshold (g), the ECU compares the slope (M) with a series of predetermined increasing slope thresholds, select one of the predetermined increasing slope thresholds having a slope equal to or immediately less than the slope (M), and execute a predetermined heat dissipation strategy respective to the selected one of the predetermined increasing slope thresholds having a slope equal to or immediately less than the slope (M); and
in response to the slope (M) is determined to be less than the slope threshold (g), the ECU assigns a value to i (i=value) and execute a predetermined heat dissipation strategy corresponding to the assigned i=value.

20. The system of claim 18, wherein when the slope (M) continues to be less than threshold slope (g) in subsequent a loop, the ECU is further configured to assign a new value to i, wherein the new value of i is one less than the previous assigned value.
